(19) United States
(12) Patent Application Publication
(10) Pub. No.: US 2013/0314099 A1
(43) Pub. Date: Nov. 28, 2013

(54) Electric Leakage Detection Apparatus

(71) Applicant: Po-Cheng Ko, Taichung City (TW)

(72) Inventor: Po-Cheng Ko, Taichung City (TW)

(21) Appl. No.: 13/899,570

(22) Filed: May 22, 2013

(30) Foreign Application Priority Data
May 23, 2012 (TW) 101118378

(51) Int. Cl. G01R 31/02

(52) U.S. Cl. CPC G01R 31/025
USPC 324/510

(57) ABSTRACT

An electric leakage detection apparatus capable of performing voltage detection on electric equipment and quantitatively displaying a testing result includes a machine body coupled with a voltage detection circuit and a welding machine electric shock prevention detection module. The voltage detection circuit includes a first voltage detection unit intended to detect whether there is electric leakage in an electric equipment, and data of a detection time, an electric leakage current, a voltage, and an electric current are displayed on a data display unit of a display control module, whereby users can directly view the whole related data to ensure safe use of electricity. The welding machine electric shock prevention detection module is intended to detect a voltage at which an auto electric shock prevention apparatus of a welding machine operates, and to display the result on the display control module, whereby improving safe use of the welding machine.

### BACKGROUND OF THE INVENTION

1. Field of the Invention

The present invention relates to a technical filed of improving safe use of electricity, and particularly to an electric leakage detection apparatus that is capable of directly displaying data being detected and tested and enabling users to efficiently control a testing condition of an electric equipment being detected, whereby improving safety of the electric equipment.

2. Related Art

In many different working places, such as construction sites, are often seen a variety of electric devices, such as welding machines, drilling machines, mixers, cutting machines, punching machines, electrical air tools, and so on. Those electric equipment are appeared to be electric leakage because of different reasons including years of use, aging of the contacts, moistened, wires damaged by bugs or rats' biting or worn out in construction sites. Therefore, different types of electric leakage detectors known as Taiwan Patent Nos.: M321969, M395874 and M395829 were invented by the applicant and widely used in the related industries. However, current electric leakage detectors are not capable of directly quantitatively displaying various data during the process of detection, but merely indicating whether a detecting result is passed. However, in some circumstances electric equipment may already be degraded to an extent of nearly disqualification. If the actual condition is not under control instantaneously, users are unable to make a timely maintenance or regulation of the electric equipment beforehand, and which may affect the safety use.

Furthermore, as shown in FIG. 5, the above-mentioned welding machine 60 is connected to electric power by a switch 70, the welding machine 60 is generally equipped with an electric shock prevention apparatus 80, and the welding machine 60 has two loop cables 61, 65 respectively connected to a welding rod handle and a base metal. The loop cables 61, 65 are respectively defined as the anode and cathode to provide a complete loop for welding. Although a no-load voltage at an output side of the welding machine 60 is only 80V, a 50V alternating current could kill people; that is, a voltage lower than 40V is regarded as a preferable voltage to keep safe. The reason for causing the welding machine 60 to be electrified is mainly because electrified portions at a secondary side of the welding machine is being touched, while the main reason for causing the secondary side of the welding machine 60 to be electrified is because a user using a welding rod handle having insulating portions that are damaged, the user is not wearing an insulating groove or such groove is wet. Thus a current welding machine 60 is required to be equipped with the electric shock prevention apparatus 80 to reduce the voltage during electrification.

Consequently, whether the electric shock prevention apparatus 80 is normally operated directly influences the safety of using the welding machine 60. Unfortunately, there are no devices to detect the electric shock prevention apparatus 80 in current industries. As a result, users cannot correctly recognize whether the electric shock prevention apparatus 80 has been operating normally, and which might affect safe of use, and could not meet users' practical requirements. Improvement on this matter is necessitated.

Hence the inventor has been researching on the problems encountered in the traditional electric leakage detectors as described above, and thanks to years of research and fabrication experience on related industries and sustained efforts, the inventor has eventually invented an electric leakage detection apparatus that successfully overcomes the current problem of fairly instantaneously displaying data being tested and inconvenience when performing detection on the electric shock prevention apparatus.

### SUMMARY OF THE INVENTION

Accordingly, an object of the present invention is to provide an electric leakage detection apparatus that is capable of instantaneously displaying a variety of data in the process of detection and test, and enables users to directly recognize an actual condition of an electric equipment being detected, whereby improving efficiency of safety management of electric equipment.

Another object of the present invention is to provide an electric leakage detection apparatus that is capable of performing detection on an electric shock prevention apparatus of a welding machine so as to enable a user to recognize whether the electric shock prevention apparatus operates normally, whereby improving safe use of the welding machine

To achieve the above-mentioned objects, the electric leakage detection apparatus comprises: a machine body comprising at least one socket coupled with a voltage detection circuit. The voltage detection circuit is configured at an output of the at least one socket, and comprises a processing unit coupled to the at least one socket through at least one first voltage detection unit. A display control module is coupled with the processing unit and the at least one first voltage detection unit, and comprises a switch selection group for a user to select a voltage to test, power input switch for inputting power to the at least one socket, an actuating testing switch for actuating a function of testing, and a data display unit for displaying data being detected. A welding machine electric shock prevention detection module is electrically connected with the display control module, and comprises two insertion holes electrically connected with a second voltage detecting unit, and respectively coupled with a positive circuit and a negative circuit for forming an electrical circuit, wherein the positive circuit is configured with a testing load, and a switch unit is configured between the positive and negative circuits. The switch unit is coupled with a control unit, and an output of the control unit is coupled with the display control module.

In this manner, the present invention is to utilize the at least one first and second voltage detection units to detect whether there is electric leakage in an electric equipment, and to display data of a detection time, an electric leakage current, a voltage, and an electric current on the data display unit of the display control module, whereby to enable a user to directly recognize and determine an actual condition from the data so as to keep control of whether the electric equipment being detected is in a condition close to disqualification. As a result, a user can make a timely replacement, maintenance, or regulation of the electric equipment being detected in order to ensure a safe use of electricity.

The invention as well as a preferred mode of use, further objectives and advantages thereof will be best understood by reference to the following detailed description of illustrative embodiments when read in conjunction with the accompanying drawings.

### BRIEF DESCRIPTION OF THE DRAWINGS

FIG. 1 is a schematic elevational view of an electric leakage detection apparatus in accordance with a preferable embodiment of the present invention;

FIG. 2 is a schematic circuit diagram of the electric leakage detection apparatus in accordance with a preferable embodiment of the present invention;

FIG. 3 is a schematic view showing a structure of a welding machine electric shock prevention detection module of the electric leakage detection apparatus of the present invention;

FIG. 4 is a schematic view showing a detection time frame for the welding machine electric shock prevention detection module of the electric leakage detection apparatus of the present invention; and

FIG. 5 is a schematic view showing a simple structure of a conventional welding machine auto electric shock prevention apparatus.

### DESCRIPTION OF THE PREFERRED EMBODIMENTS

The present invention relates to an electric leakage detection apparatus. Direction-related wordings, such as “front”, “rear”, “left”, “right”, “top”, “bottom”, “upper”, “lower”, “horizontal” and “vertical”, are used hereunder in conjunction with the accompanying drawings. The direction-related wordings are intended for description and comprehension of the present invention rather than restriction of the present invention.

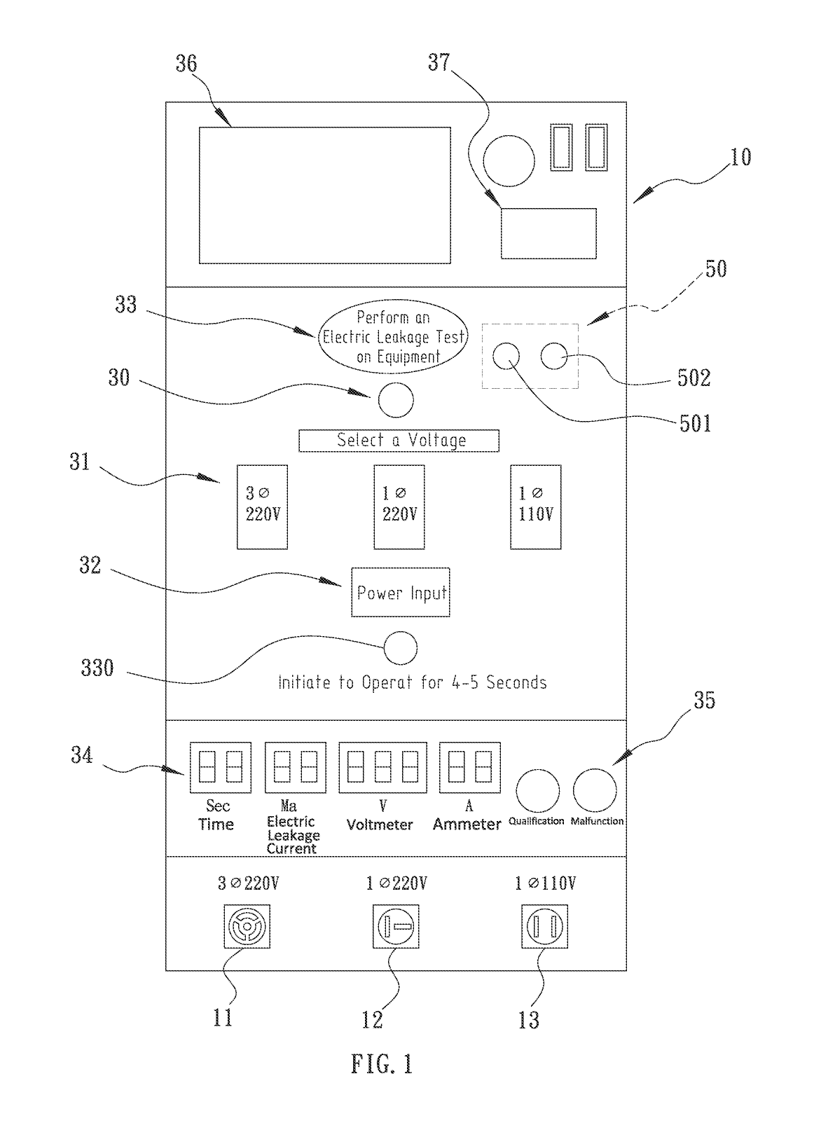

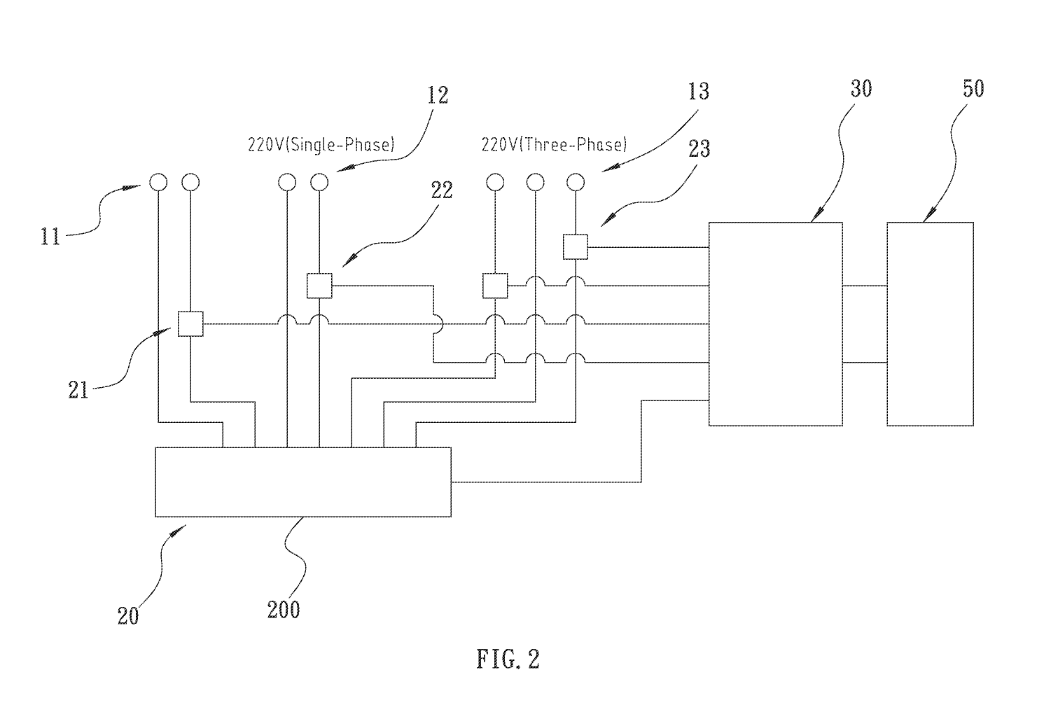

The present invention relates to an electric leakage detection apparatus capable of detecting electric equipment at any time. Referring to FIGS. 1 and 2, the electric leakage detection apparatus comprises at least one voltage detection circuit 20, a display control module 30, and a welding machine electric shock prevention detection module 50.

Referring to FIGS. 1 to 3 for detailed description of preferable embodiments of the present invention, the machine body 10 has a case shape, the voltage detection circuit 20 is configured in the machine body 10, and the display control module 30 is disposed on a surface of the machine body 10 for a user's control and monitor. The machine body 10 comprises at least one socket which is coupled with the voltage detection circuit 20. In this embodiment, the machine bogy 10 has three the sockets which are respectively defined as a first socket 11 for electric equipment operating at 110 voltage (V), a second socket 12 for single-phase electric equipment operating at 220V, and a third socket 13 for three-phase electric equipment operating at 220V.

The voltage detection circuit 20 is configured between the first, second and third sockets 11, 12 and 13 of the machine body 10 and the display control module 30. The voltage detection circuit 20 comprises a processing unit 200, and is coupled to the first socket 11 of the machine body 10 through a first voltage detection unit 21 for detecting 110V electric equipment. Furthermore, the processing unit 200 is coupled to the second socket 12 through a single-phase voltage detection unit 22 for detecting 220V single-phase equipment. Also, the processing unit 200 is coupled to the third socket 13 through a three-phase voltage detection unit 23 for detecting 220V three-phase equipment.

The display control module 30 is coupled with the processing unit 200 of the voltage detection circuit 20, the first voltage detection unit 21, the single-phase voltage detection unit 22, and the three-phase voltage detection unit 23. The display control module 30 comprises a switch selection group 31 from which a user is able to select a voltage to test. The switch selection group 31 comprises multiple switches corresponding to the first, second and third sockets 11, 12 and 13. Furthermore, the display control module 30 comprises a power input switch 32 for inputting power to the corresponding to the first, second and third sockets 11, 12 and 13, and an actuating testing switch 33 for actuating a function of testing. The actuating testing switch 33 comprises an operation indicator light 330 to enable a user to recognize whether the electric leakage detection apparatus is in operation. The display control module 30 comprises a data display unit 34. The data display unit 34 comprises an LED display which is capable of displaying a detection time, an electric leakage current, a voltage, and an electric current. The display control module 30 further comprises a qualification indication unit 35 which includes a qualification indication element and a malfunction indication element. Moreover, the display control module 30 comprises a display unit 36 which is capable of being a liquid crystal display (LCD) for displaying a variety of posting pictures and texts. The display control module 30 further comprises a label printing unit 37 which is operated in conjunction with the qualification indication unit 35 to print a qualification label after detecting.

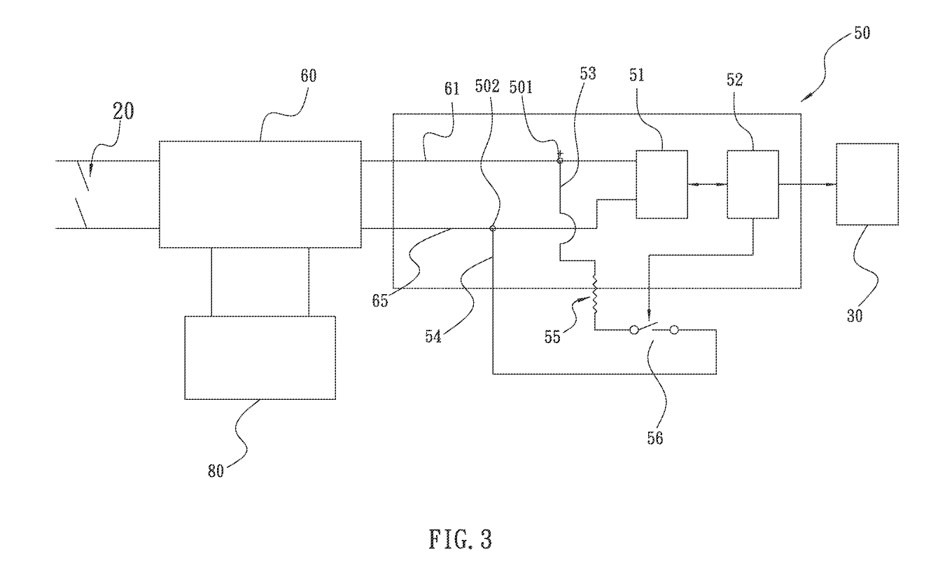

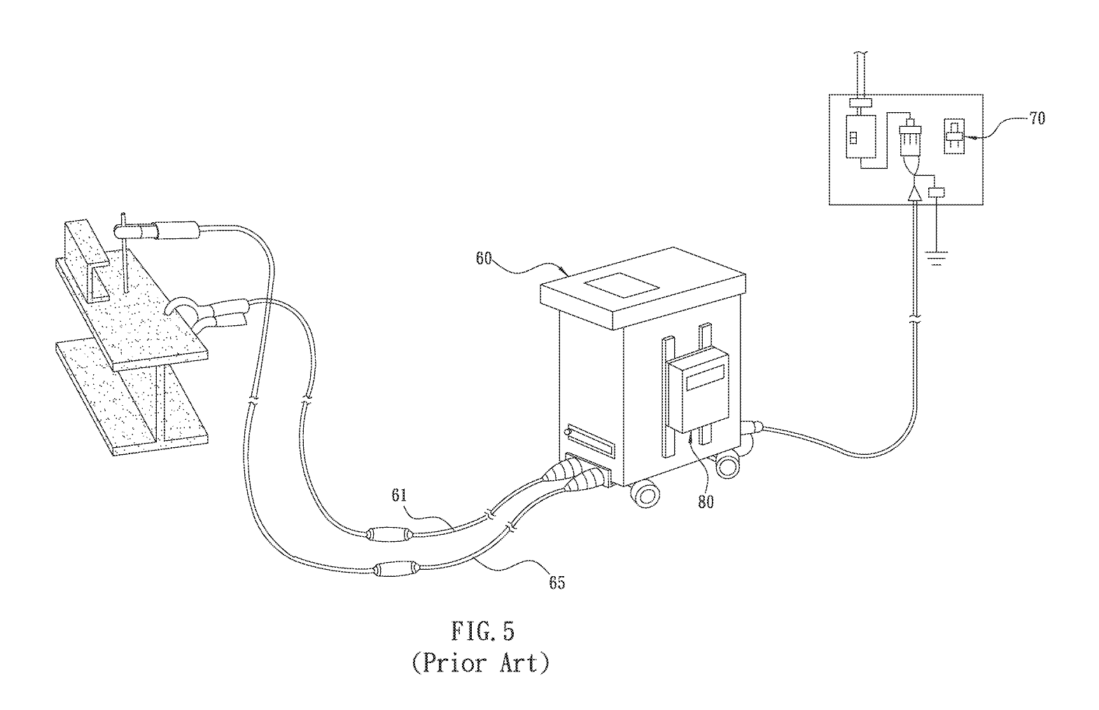

The welding machine electric shock prevention detection module 50 is electrically connected with the display control module 30, and comprises two insertion holes 501 and 502 disposed on the machine body 10 for being connected with two loop cables 61 and 65 of the welding machine 60 (as shown in FIG. 5). As shown in FIG. 3, the insertion holes 501 and 502 are further electrically connected with a second voltage detecting unit 51 for detecting a voltage between the loop cables 61 and 65 of the welding machine 60. The second voltage detecting unit 51 is coupled with a control unit 52 for obtaining values of voltages and controlling the operation of detecting. The two insertion holes 501 and 502 for being connected with the positive and negative circuit cables 61 and 65 of the welding machine 60 are respectively coupled with a positive circuit 53 and a negative circuit 54 for forming an electrical circuit, wherein the positive circuit 53 is configured with a testing load 55, and a switch unit 56 is configured between the positive and negative circuits 53 and 54. The switch unit 56 is coupled with the control unit 52 by which an open circuit and a closed circuit of the switch unit 56 is controlled in order to initiate the testing load 55 to enable the second voltage detecting unit 51 to perform voltage detection. An output of the control unit 52 is coupled with the display control module 30 so as to enable the LED display of the data display unit 34 of the display control module 30 to display the detection time, the electric leakage current, the voltage, and the electric current. The output of the control unit 52 is coupled with the qualification indication unit 35 and the display unit 36 for indicating a state of qualification or malfunction, and the label printing unit 37 is utilized to print a qualification label after detecting.

In this manner, the electric leakage detection apparatus is capable of instantaneously displaying the data being detected.

Referring to FIGS. 1 and 2 first for the operation of the electric leakage detection apparatus of the present invention, an electric equipment to be tested is selectively coupled to the corresponding first, second and third sockets 11, 12 and 13 of the machine body 10 according to a voltage at which the electric equipment to be tested operates, such as 110V, single-phase 220V, or three-phase 220V.

Next, switch on a corresponding switch of the switch selection group 31 of the display control module 30; then, initiate the power input switch 32 of the display control module 30 to allow electric power to be input to the electric equipment to be tested; and then press the actuating testing switch 33 of the display control module 30 to enable the processing unit 200 of the voltage detection circuit 20 and the corresponding first voltage detection unit 21, the single-phase voltage detection unit 22, or the three-phase voltage detection unit 23 to start to perform an electric leakage test on the electric equipment to be tested.

Accordingly, a detection time, an electric leakage current, a voltage, and an electric current are respectively indicated by the LED display of the data display unit 34 of the display control module 30, whereby through the data display unit 34 a user is allowed to directly control the data being detected and tested. Simultaneously, based on a preset standard, the qualification indication unit 35 of the display control module 30 is to indicate a testing result over the qualification indication element and the malfunction indication element. Finally, under the control of the qualification indication unit 35, the label printing unit 37 of the display control module 30 is capable of correspondingly printing a qualification label.

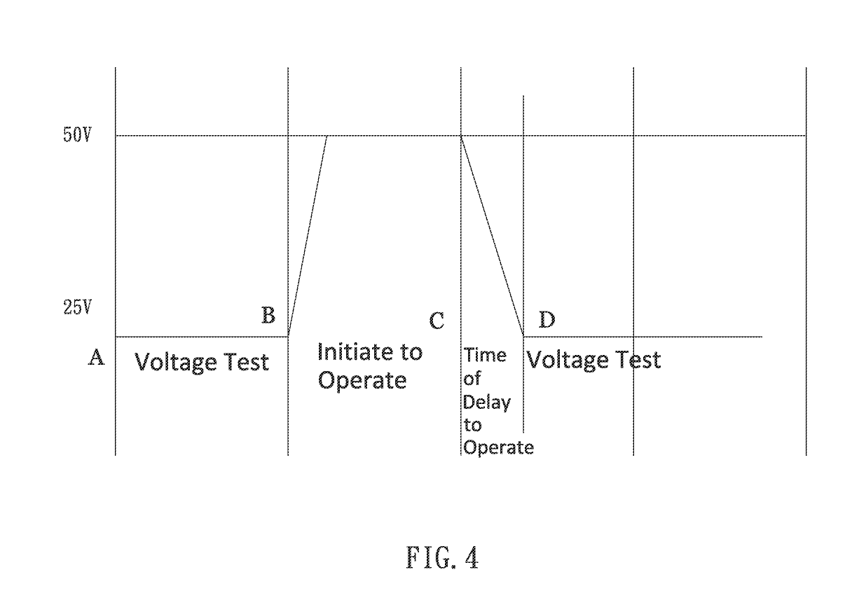

For testing an electric shock prevention apparatus 80 of the welding machine 60, the two loop cables 61 and 65 of the welding machine 60 are respectively connected to the insertion holes 501 and 502 of the welding machine electric shock prevention detection module 50 disposed on the machine body 10. At the same time when the welding machine 60 is powered on, a user is able to utilize the control unit 52 of the welding machine electric shock prevention detection module 50 to initiate the switch unit 56 to enable the second voltage detecting unit 51 to instantaneously detect voltage, whereby a testing result is simultaneously displayed on the display control module 30 in order to recognize whether the welding machine 60 is operating at a voltage within a prescribed range during a whole course of operation as show in FIG. 4. Therefore, whether the welding machine electric shock prevention detection module 50 is operating normally can be efficiently detected and recognized.

With the above described structure and operation, the present invention is to utilize the first voltage detection unit 21, the single-phase voltage detection unit 22, and the three-phase voltage detection unit 23 of the voltage detection circuit 20 to detect whether there is electric leakage in an electric equipment, and to display data of a detection time, an electric leakage current, a voltage, and an electric current on the data display unit 34 of the display control module 03, whereby to enable a user to directly recognize and determine an actual condition from the data so as to keep control of whether the electric equipment being detected is in a condition close to disqualification. As a result, a user can make a timely replacement, maintenance, or regulation of the electric equipment being detected in order to ensure a safe use of electricity.

Additionally, by utilizing configurations that the second voltage detecting unit 51 of the welding machine electric shock prevention detection module 50 is coupled with the loop cables 61 and 65 of the welding machine 60, the switch unit 56 is controlled by the control unit 52 for the open circuit and closed circuit to initiate the testing load 55 for the second voltage detecting unit 51 to perform voltage detection, the display control module 30 is capable of displaying a testing result, and a qualification label is capable of being stuck onto the electric shock prevention apparatus 80 for users' recognition, the welding machine is therefore being used much more safe by which value added and economic benefits thereof are greatly increased.

It is understood that the invention may be embodied in other forms within the scope of the claims. Thus the present examples and embodiments are to be considered in all respects as illustrative, and not restrictive, of the invention defined by the claims.

What is claimed is:

1. An electric leakage detection apparatus, comprising:
a machine body comprising at least one socket coupled with a voltage detection circuit;
the voltage detection circuit configured at an output of the at least one socket of the machine body, and comprising a processing unit coupled to the at least one socket through at least one first voltage detection unit;
a display control module coupled with the processing unit and the at least one first voltage detection unit of the voltage detection circuit, and comprising a switch selection group for a user to select a voltage to test, a power input switch for inputting power to the at least one socket, an actuating testing switch for actuating a function of testing, and a data display unit for displaying data being detected; and
a welding machine electric shock prevention detection module electrically connected with the display control module, and comprising two insertion holes electrically connected with a second voltage detecting unit, and respectively coupled with a positive circuit and a negative circuit for forming an electrical circuit, wherein the positive circuit is configured with a testing load, and a switch unit is configured between the positive and negative circuits, the switch unit being coupled with a control unit, and an output of the control unit coupled with the display control module; and whereby the electric leakage detection apparatus is capable of instantaneously displaying the data being detected.

2. The electric leakage detection apparatus of claim 1, wherein the machine body comprises three the sockets which are respectively defined as a first socket for electric equipment operating at 110 voltage, a second socket for single-phase electric equipment operating at 220 voltage, and a third socket for three-phase electric equipment operating at 220 voltage, and the voltage detection circuit comprises a voltage detection unit out of the at least one first voltage detection unit for correspondingly detecting 110 voltage, a single-phase voltage detection unit out of the at least one first voltage detection unit for correspondingly detecting single-phase 220 voltage, and a three-phase voltage detection unit out of the at least one first voltage detection unit for correspondingly detecting three-phase 220 voltage.

3. The electric leakage detection apparatus of claim 1, wherein the actuating testing switch of the display control module comprises an operation indicator light to enable a user to recognize whether the electric leakage detection apparatus is in operation.

4. The electric leakage detection apparatus of claim 1, wherein the data display unit of the display control module comprises an LED display being capable of displaying a detection time, an electric leakage current, a voltage, and an electric current.

5. The electric leakage detection apparatus of claim 1, wherein the display control module further comprises a qualification indication unit which includes a qualification indication element and a malfunction indication element.

6. The electric leakage detection apparatus of claim 1, wherein the display control module further comprises a display unit which is capable of being a liquid crystal display (LCD).

7. The electric leakage detection apparatus of claim 1, wherein the display control module further comprises a label printing unit for printing a qualification label.
